(19) United States
(12) Patent Application Publication
(10) Pub. No.: US 2013/0105647 A1
(43) Pub. Date: May 2, 2013

(54) MOUNTING APPARATUS FOR EXPANSION CARD

(71) Applicants: TING-TING HE, Wuhan City (CN); ZHI-PING WU, Wuhan City (CN); GUI-FANG YANG, Wuhan City (CN)

(72) Inventors: TING-TING HE, Wuhan City (CN); ZHI-PING WU, Wuhan City (CN); GUI-FANG YANG, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/554,101

(22) Filed: Jul. 20, 2012

(30) Foreign Application Priority Data
Oct. 27, 2011 (CN) 201110331564.X

(51) Int. Cl. H05K 7/14

(52) U.S. Cl. 248/221.11

(57) ABSTRACT

A mounting apparatus includes a chassis, a cover secured to the chassis, an enclosure, a mounting member, a limiting member, and a blocking member. A main board is installed on the chassis and defines an insertion slot. The mounting member engages with the chassis. The limiting member is rotatably secured to the chassis and abuts the mounting member. The blocking member is engaged with the chassis. When an expansion card is received in the insertion slot, the mounting member is secured to the expansion card, and the blocking member abuts the expansion card, for preventing the expansion card from disengaging from the insertion slot; The cover abuts the limiting member to prevent the limiting member from rotating relative to the chassis. The cover abuts the blocking member to prevent the blocking member from disengaging from the expansion card.

### BACKGROUND

1. Technical Field

The present disclosure relates to mounting apparatus, and particularly to a mounting apparatus for expansion card.

2. Description of Related Art

A computer system may include a plurality of expansion cards, such as sound cards, video cards, and graphics cards, for enhancing capabilities of the computer system. As performance of the computer develops, the size of the expansion card becomes larger. The expansion card is inserted into a securing slot of a circuit board, a first end of the expansion card is secured to the rear plate of the computer, and a second end is left free and unsecured. However, vibration and shocks on an unfixed expansion card may result in damage to the card subsequently and soon.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a mounting apparatus and a plurality of expansion cards.

FIG. 2 is an enlarged view of a circled portion II of FIG. 1.

FIG. 3 is an isometric view of a limiting member of the mounting apparatus of FIG. 1.

FIG. 4 is an isometric view of a blocking member of the mounting apparatus of FIG. 1.

FIG. 5 is a partly assembled view of the mounting apparatus and the plurality of expansion cards of FIG. 1.

FIG. 6 is similar to FIG. 5, but viewed from a different aspect.

FIG. 7 is an enlarged view of a circled portion VII of FIG. 5.

FIG. 8 is an assembled view of the mounting apparatus and the plurality of expansion cards of FIG. 1 with a cutaway cover.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one”.

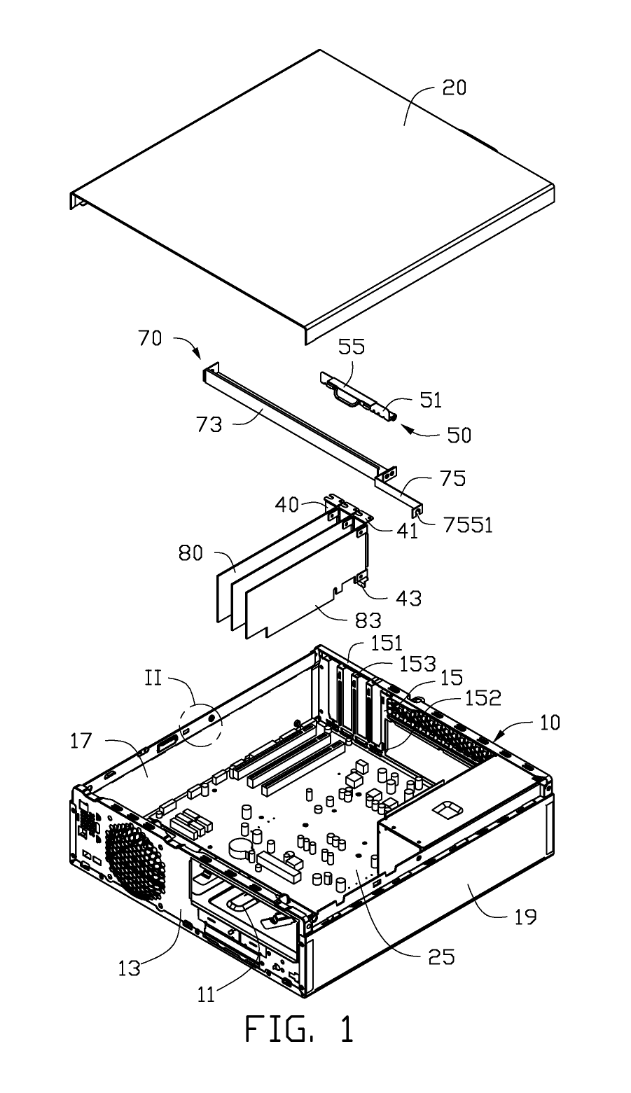

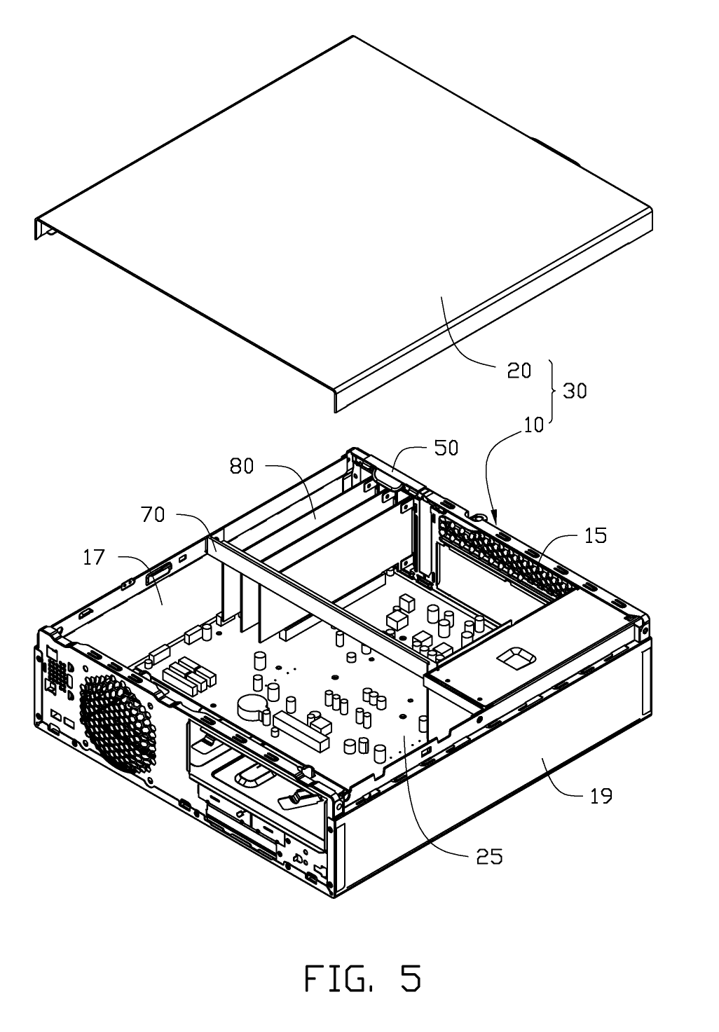

Referring to FIGS. 1 and 5, a mounting apparatus in accordance with an embodiment is provided which is capable of securing a plurality of expansion cards 80. The mounting apparatus includes an enclosure 30, a plurality of mounting members 40, a limiting member 50, and a blocking member 70. The expansion cards 80 may be, for example, sound cards, video cards, or graphics cards, or other peripheral component interconnect (PCI) cards. A sticking portion 83 extends from bottom portion of each of the plurality of expansion cards 80.

Each the mounting members 40 is attached to a back portion of each expansion card 80. A latch piece 41 is located at a first end of the mounting member 40, and an insertion portion 43 extends from a second end of the mounting member 40.

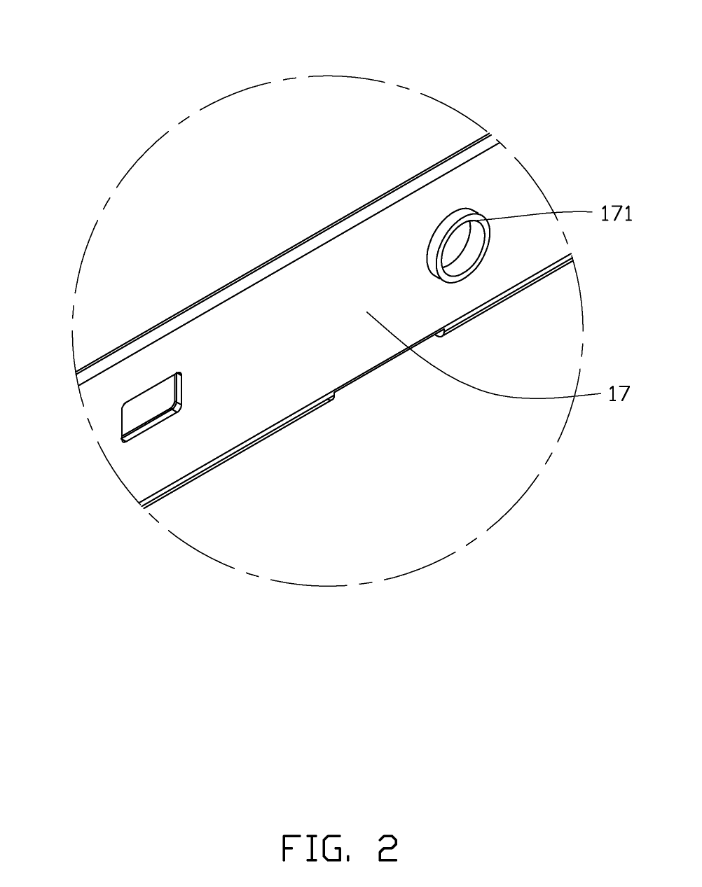

The enclosure 30 includes a chassis 10 and a cover 20. The chassis 10 includes a bottom plate 11, a front plate 13, a rear plate 15, a first sidewall 17, and a second sidewall 19. The front plate 13 and the rear plate 15 extend from opposite sides of the bottom plate 11. The first sidewall 17 and the second sidewall 19 extend from the other opposite sides of the bottom plate 11. In one embodiment, the first sidewall 17 is substantially parallel to the second sidewall 19, and the first sidewall 17 is perpendicularly connected to the front plate 13 and the rear plate 15. A protrusion 171 (shown in FIG. 2) is located on an inner side of each of the first sidewall 17 and the second sidewall 19. A main board 25 is attached on the bottom plate 11. A plurality of insertion slots 251 are defined in the main board 25, for receiving the sticking portions 83.

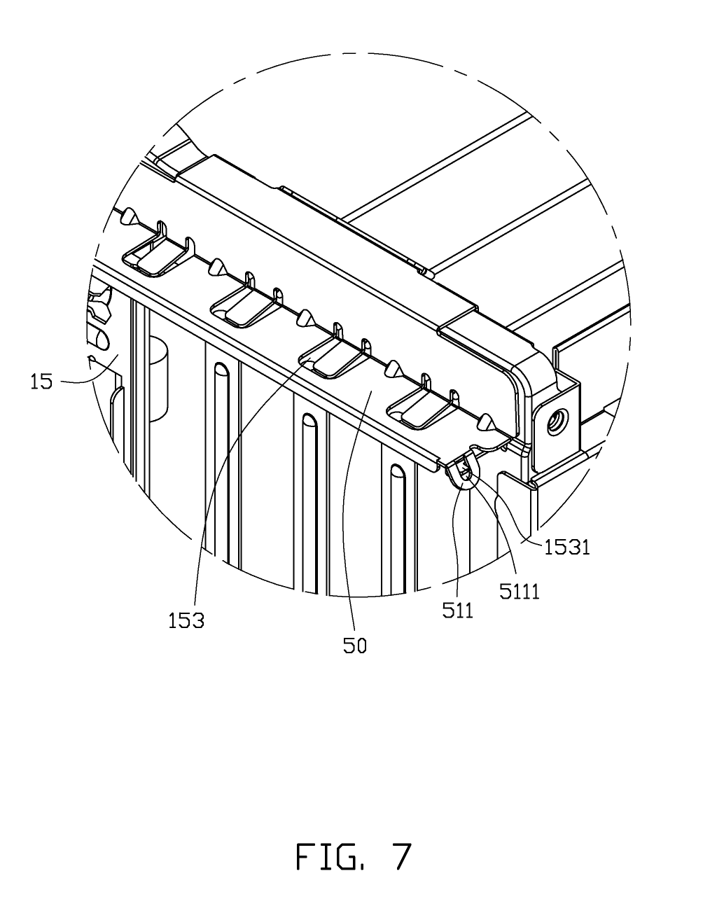

A flange 151 extends outwards from a top edge of the rear plate 15. A plurality of inserting holes 152 is defined in the rear plate 15 and adjacent to the main board 25. Each insertion portion 43 is configured to be inserted into each inserting hole 152. An opening (not labeled) is defined in the rear plate 15 and below the flange 151. A limiting piece 153 (shown in FIG. 7) extends outwards from the rear plate 15 and is located on the bottom edge of the opening. The limiting piece 153 is substantially parallel to the flange 151. Two pivot portions 1531 (shown in FIG. 7) are respectively located on opposite ends of the limiting piece 153.

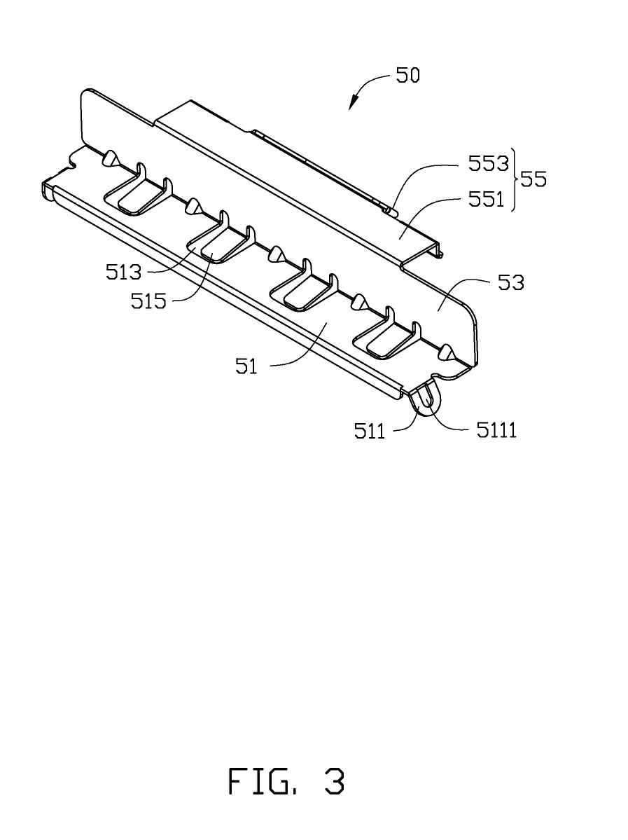

Referring to FIG. 3, the limiting member 50 includes a pressing portion 51, a connecting portion 53, and an engaging portion 55. Two latch tabs 511 respectively extend outwards from opposite ends of the pressing portion 51. A latch hole 5111 is defined in each of the two latch tabs 511. The connecting portion 53 extends from the pressing portion 51. The pressing portion 51 defines a plurality of cutouts 513 extending to the connecting portion 53. A plurality of resilient pieces 515 extends from the connecting portion 53. Each of the plurality of resilient pieces 515 is deformable so as to be receivable in each of the plurality of cutouts 513. Each of the resilient pieces 515 is configured to abut the latch piece 41 of the plurality of mounting members 40. In one embodiment, the connecting portion 53 is substantially perpendicular to the pressing portion 51. The plurality of resilient pieces 515 are located on a plane. An acute angle is defined between the plane and the pressing portion 51. An obtuse angle is defined between the plane and the connecting portion 53. The engaging portion 55 includes an engaging board 551 and an operating portion 553 connected to the engaging board 551. The engaging board 551 extends from the connecting portion 53 and is opposite to the pressing portion 51. In one embodiment, the engaging board 551 is substantially parallel to the pressing portion 51 and is perpendicularly connected to the connecting portion 53.

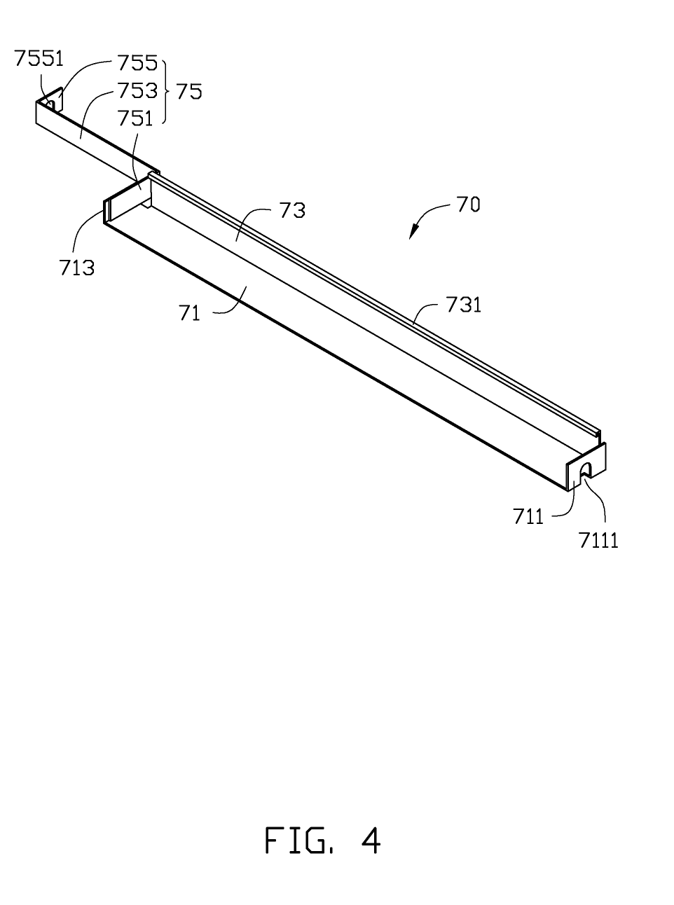

Referring to FIG. 4, the blocking member 70 includes a limiting portion 71, a resisting portion 73, and a linking portion 75. A first stopping piece 711 extends upwards from a first end of the limiting portion 71, and an installation piece 713 extends upwards from second end opposite to the first end of the limiting portion 71. The first stopping piece 711 defines a first stopping hole 7111, extending from the limiting portion 71. The resisting portion 73 extends from an edge of the limiting portion 71. The resisting portion 73 is located between the first stopping piece 711 and the installation piece 713. In one embodiment, the first stopping piece 711 is substantially perpendicularly connected to the limiting portion 71, the installation piece 713 is substantially perpendicularly connected to the limiting portion 71, and the resisting portion 73 is substantially perpendicular to the limiting portion 71. A hem 731 is formed by being bent from a distal end of the resisting portion 73.

The linking portion 75 includes a securing piece 751, a connecting piece 753, and a second stopping piece 755. The securing piece 751 is secured to the installation piece 713 via bolts or screws. The connecting piece 753 connects the securing piece 751 to the stopping piece 755. The securing piece 751 and the stopping piece 755 are respectively located on opposite ends of the connecting piece 753 and located on opposite sides of the connecting piece 753. In one embodiment, the securing piece 751 is substantially perpendicular to the connecting piece 753, and the stopping piece 755 is substantially perpendicular to the connecting piece 753. A second stopping hole 7551 is defined in the second stopping piece 755.

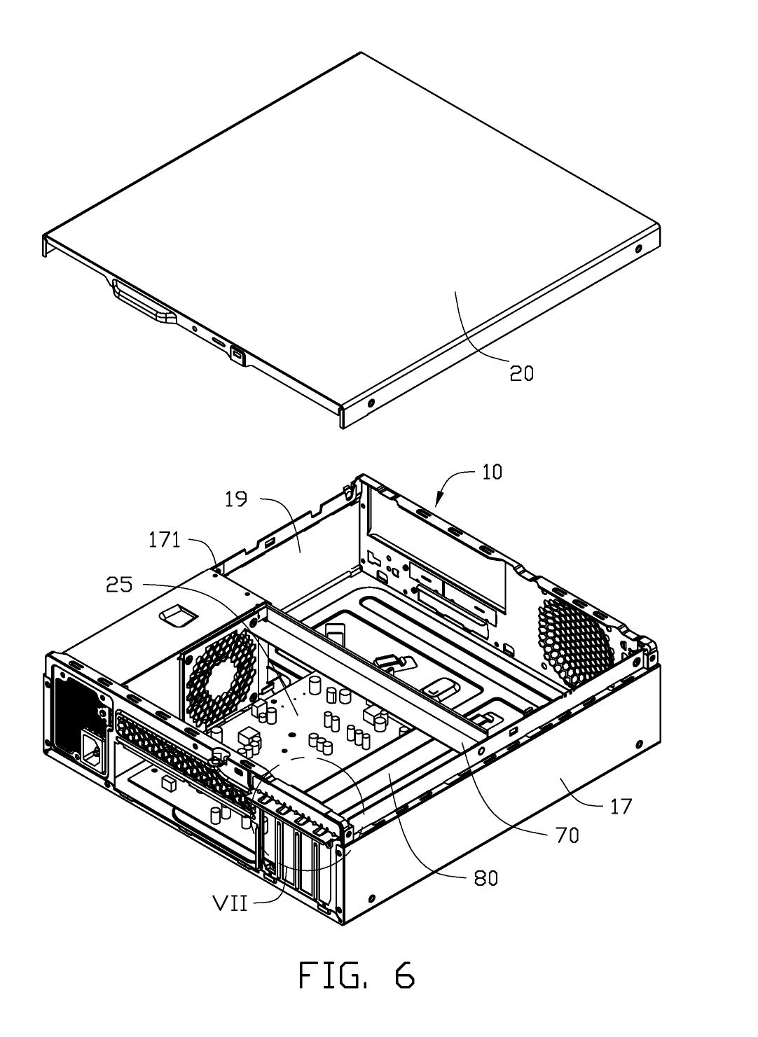

Referring to FIGS. 5-6, in assembly, the latch piece 41 of the mounting member 40 extends through the opening and abuts the limiting piece 153. The insertion portion 43 of the mounting member 40 is inserted into the inserting hole 152. The sticking portion 83 of each expansion card 80 is inserted into the insertion slot 251 of the main board 25.

In assembly of the limiting member 50, the two latch tabs 511 are stretched elastically, until the two pivot portions 1531 can be inserted into the latch holes 5111. The limiting member 50 is rotatably secured to the rear plate 15. The engaging portion 55 is engaged with the flange 151.

In assembly of the blocking member 70, the blocking member 70 is put into the chassis 10. The first stopping piece 711 and the second stopping piece 755 respectively abut the first sidewall 17 and the second sidewall 19. The protrusions 171 of the first sidewall 17 and the second sidewall 19 are respectively engaged in the first stopping hole 7111 and the second stopping hole 7551.

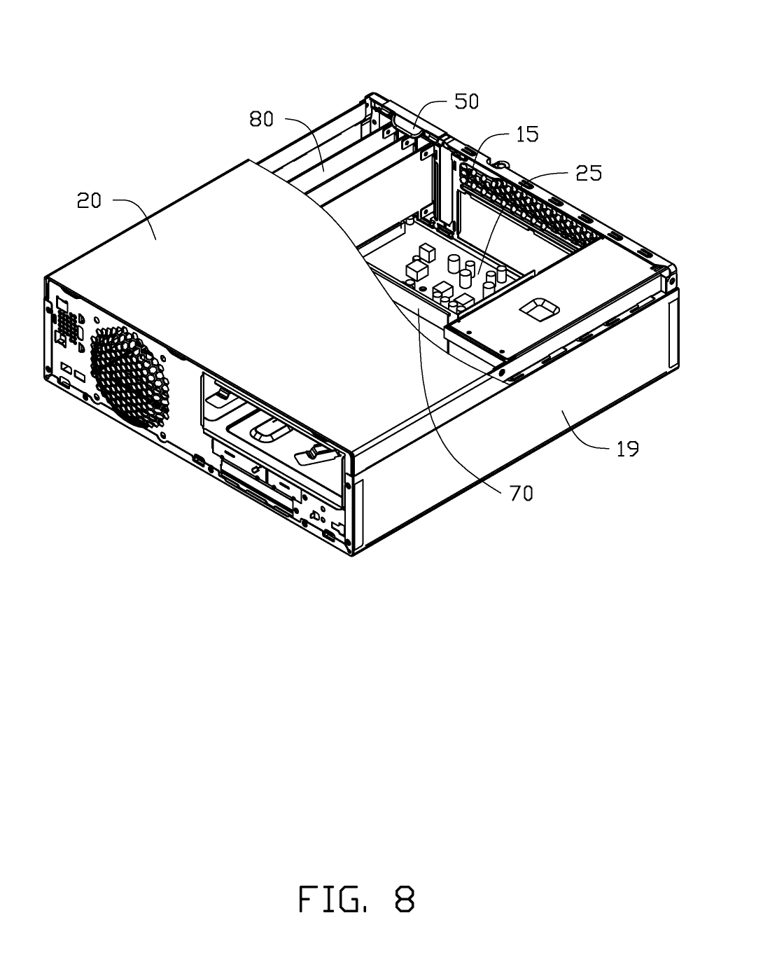

Referring to FIG. 8, the cover 20 is installed onto the chassis 10 to abut the hem 731 and the engaging board 551. Each resilient piece 515 is elastically deformed to abut the latch piece 41 of each mounting member 40. The limiting portion 71 of the blocking member 70 abuts a second end opposite to the first end of each expansion card 80, for preventing the disengagement of the expansion card 80 from the insertion slot 251.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A mounting apparatus comprising:
a chassis, a main board installed on the chassis, the main board defining an insertion slot;
a cover secured to the chassis;
a mounting member, engaged with the chassis;
a limiting member, the limiting member rotatably secured to the chassis and abuts the mounting member; and
a blocking member, the blocking member engaged with the chassis; wherein when an expansion card is received in the insertion slot, the mounting member is secured to the expansion card, the blocking member abuts the expansion card, for preventing the expansion card from disengaging from the insertion slot; the cover abuts the limiting member to prevent the limiting member from rotating relative to the chassis, and the cover abuts the blocking member to prevent the blocking member from disengaging from the expansion card.

2. The mounting apparatus of claim 1, wherein the chassis comprises a first sidewall wall and a second sidewall, two protrusions are respectively located on the first sidewall and the second sidewall, and the blocking member defines a first stopping hole and a second stopping hole for the two protrusions to engage therein to secure the blocking member to the chassis.

3. The mounting apparatus of claim 1, wherein the blocking member comprises a limiting portion and a resisting portion connected to the limiting portion, the limiting portion is configured to abut the expansion card, and a hem extend from the resisting portion, and abuts the cover.

4. The mounting apparatus of claim 3, wherein the resisting portion is substantially parallel to the limiting portion.

5. The mounting apparatus of claim 3, wherein a first stopping piece is located on the limiting portion, the blocking member further comprises a linking portion secured to the limiting portion, the linking portion comprise a second stopping piece, and the first stopping piece and the second stopping piece are engaged with the chassis.

6. The mounting apparatus of claim 5, wherein the linking portion further comprises a securing piece and a connecting piece, the connecting piece connects the securing piece to the second stopping piece, an installation piece is located on a second end of the limiting portion, and the securing piece is secured to the installation piece.

7. The mounting apparatus of claim 5, wherein the first stopping piece is substantially parallel to the second stopping piece.

8. The mounting apparatus of claim 1, wherein the chassis comprises a rear plate and a limiting piece, the limiting piece extends from the rear plate, two pivot portions are located on the limiting piece; and the limiting member comprises a pressing portion and two latch tabs located on the pressing portion, and each of the two latch tabs defines a latch hole for each of the pivot portions to engage therein to rotatably secure the limiting member to the chassis.

9. The mounting apparatus of claim 8, wherein the limiting member further comprises a connecting portion and an engaging portion connected to the connecting portion, the connecting portion is connected to the pressing portion, and a flange extends from the rear plate, the engaging portion is engaged with the flange.

10. The mounting apparatus of claim 9, wherein the pressing portion define a cutout extending to the connecting portion, a resilient piece extends from the connecting portion, and the resilient piece is elastically deformable to be received in the cutout and abuts the mounting member.

11. The mounting apparatus of claim 10, wherein an acute angle is defined between the resilient piece and the pressing portion, and an obtuse angle is defined between the resilient piece and the connecting portion.

12. A mounting apparatus comprising:
a chassis, a main board installed on the chassis, and the main board defining an insertion slot;
a cover secured to the chassis;
a mounting member engaged with the chassis;
a limiting member, the limiting member rotatably secured to the chassis and abuts the mounting member; and
a blocking member, the blocking member engaged with the chassis and comprises a limiting portion and a resisting portion;
wherein when an expansion card is received in the insertion slot, the mounting member is secured to the expansion card, and the blocking member abuts the expansion card, for preventing the expansion card from disengaging from the insertion slot; the cover abuts the limiting member to prevent the limiting member from rotating relative to the chassis, and the resisting portion is against the cover for preventing the blocking member from disengaging from the expansion card.

13. The mounting apparatus of claim 12, wherein the chassis comprises a first sidewall wall and a second sidewall, two protrusions are respectively located on the first sidewall and the second sidewall, and the blocking member defines a first stopping hole and a second stopping hole for the two protrusions to engage therein to secure the blocking member to the chassis.

14. The mounting apparatus of claim 12, wherein the resisting portion is substantially parallel to the limiting portion.

15. The mounting apparatus of claim 12, wherein a first stopping piece extends from the limiting portion, the blocking member further comprises a linking portion secured to the limiting portion, the linking portion comprises a second stopping piece, and the first stopping piece and the second stopping piece are engaged with the chassis.

16. The mounting apparatus of claim 15, wherein the linking portion further comprises a securing piece and a connecting piece, the connecting piece connects the securing piece to the second stopping piece, an installation piece extends from the limiting portion, and the securing piece is secured to the installation piece.

17. The mounting apparatus of claim 15, wherein the first stopping piece is substantially parallel to the second stopping piece.

18. The mounting apparatus of claim 12, wherein the chassis comprises a rear plate and a limiting piece, the limiting piece extends from the rear plate, two pivot portions are located on the limiting piece; and the limiting member comprises a pressing portion and two latch tabs located on the pressing portion, and each of the two latch tabs defines a latch hole for each of the pivot portions to engage therein to rotatably secure the limiting member to the chassis.

19. The mounting apparatus of claim 18, wherein the limiting member further comprises a connecting portion and an engaging portion connected to the connecting portion, the connecting portion is connected to the pressing portion, and a flange extends from the rear plate, the engaging portion is engaged with the flange.

20. The mounting apparatus of claim 19, wherein the pressing portion define a cutout extending to the connecting portion, a resilient piece extends from the connecting portion, and the resilient piece is elastically deformed to be received in the cutout and abuts the mounting member.
